(19) United States
(12) Patent Application Publication
(10) Pub. No.: US 2023/0069800 A1
(43) Pub. Date: Mar. 2, 2023

(54) SEMICONDUCTOR DEVICE AND METHOD FOR MANUFACTURING SEMICONDUCTOR DEVICE

(71) Applicant: KIOXIA CORPORATION, Tokyo (JP)

(72) Inventor: Hideto TAKEKIDA, Nagoya Aichi (JP)

(21) Appl. No.: 17/684,174

(22) Filed: Mar. 1, 2022

(30) Foreign Application Priority Data
Sep. 2, 2021 (JP) 2021-143336

(51) Int. Cl. H01L 23/00; H01L 25/065; H01L 25/18; H01L 25/00

(52) U.S. Cl. CPC H01L 24/08; H01L 25/0657; H01L 25/18; H01L 24/80; H01L 25/50; H01L 2224/08145; H01L 2224/80895; H01L 2224/80896; H01L 2924/1431; H01L 2924/14511

(57) ABSTRACT

A semiconductor device includes a first substrate and a plurality of electrode layers above the first substrate and separated from each other in a first direction. The device includes a plurality of plugs provided on upper surfaces or lower surfaces of the plurality of electrode layers and a plurality of columnar portions in the plurality of electrode layers and extending in the first direction. A charge storage layer is between a semiconductor layer of the columnar portions and the electrode layers. A second substrate is provided above the plurality of electrode layers. A plurality of first transistors is provided on an upper surface of the first substrate and are electrically connected to the plurality of plugs. A plurality of second transistors is provided on a lower surface of the second substrate and are electrically connected to the plurality of columnar portions.

### CROSS-REFERENCE TO RELATED APPLICATION

This application is based upon and claims the benefit of priority from Japanese Patent Application No. 2021-143336, filed Sep. 2, 2021, the entire contents of which are incorporated herein by reference.

### FIELD

Embodiments described herein relate generally to a semiconductor device and a method for manufacturing the same.

### BACKGROUND

While it generally preferable to reduce the die area of semiconductor chip, certain circuit types on the semiconductor chip may limit the potential reduction of the die area. For example, a peripheral circuit on a memory chip may limit the possible reduction of the die area.

### BRIEF DESCRIPTION OF THE DRAWINGS

FIG. 1 is a block diagram of a semiconductor device according to a first embodiment.

FIG. 2 is a cross-sectional view of a semiconductor device according to a first embodiment.

FIG. 3 is an enlarged cross-sectional view of a semiconductor device according to a first embodiment.

FIG. 4 is a cross-sectional view depicting aspects related to a method for manufacturing a semiconductor device according to a first embodiment.

FIG. 5 is a cross-sectional view depicting aspects related to a method for manufacturing a semiconductor device according to a first embodiment.

FIG. 6 is a cross-sectional view of a semiconductor device of a first modification.

FIG. 7 is a cross-sectional view illustrating additional aspects of a semiconductor device according to a first embodiment.

FIG. 8 is a cross-sectional view illustrating additional aspects of a semiconductor device of a first modification.

FIG. 9 is a cross-sectional view of a semiconductor device of a second modification.

FIG. 10 is a cross-sectional view of a semiconductor device of a third modification.

FIGS. 11A, 11B, and 11C are plan views illustrating aspects of the structure of a semiconductor device according to a first embodiment.

FIG. 12 is a plan view illustrating additional aspects of a semiconductor device according to a first embodiment.

FIG. 13 is a cross-sectional view of a semiconductor device according to a second embodiment.

FIG. 14 is a cross-sectional view of a semiconductor device of a modification of the second embodiment.

### DETAILED DESCRIPTION

Embodiments relate to reducing chip area (die size) of semiconductor devices and a method for manufacturing such devices with reduced chip area.

In general, according to one embodiment, there is provided a semiconductor device including a first substrate and a plurality of electrode layers provided above the first substrate and separated from each other in a first direction. The device further includes a plurality of plugs provided on upper surfaces or lower surfaces of the plurality of electrode layers, respectively, a plurality of columnar portions including a semiconductor layer provided in the plurality of electrode layers and extending in the first direction. A charge storage layer is provided between the semiconductor layer of the columnar portions and the plurality of electrode layers. A second substrate is provided above the plurality of electrode layers. The device further includes a plurality of first transistors provided on an upper surface of the first substrate and electrically connected to the plurality of plugs, respectively. The device further includes a plurality of second transistors provided on a lower surface of the second substrate and electrically connected to the plurality of columnar portions, respectively.

Hereinafter, certain example embodiments of the present disclosure will be described with reference to the drawings. In general, the drawings are schematic and depicted dimensions and relative sizes of components and the like are selected primarily for the purposes of graphical clarity. As such, the depicted sizes, relative sizes, and the like do not necessarily reflect those of an actual device. In the drawings, the same elements, components, aspects, etc. are denoted using the same reference numerals, and description of such elements, components, aspects, etc. may be omitted after an initial description.

### First Embodiment

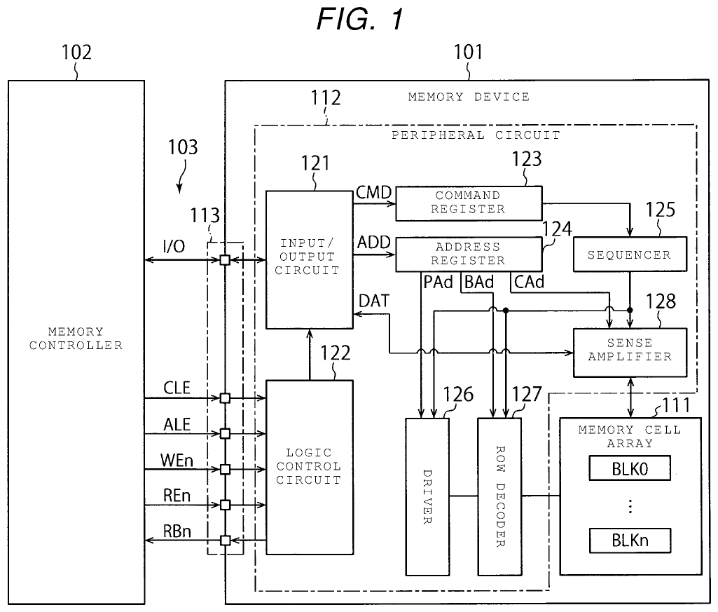

FIG. 1 is a block diagram illustrating a circuit configuration of a semiconductor device of a first embodiment.

The semiconductor device of this first embodiment includes a memory device 101, a memory controller 102, and a bus 103 (including a plurality of signal and/or data I/O lines). The memory device 101 has a plurality of memory cells for storing data or the like. The memory controller 102 controls operations of the memory device 101. The memory device 101 and the memory controller 102 are electrically connected by the bus 103 and together form a memory system.

The memory device 101 includes a memory cell array 111, a peripheral circuit 112, and a plurality of connection pads 113. The memory cell array 111 includes blocks BLK0 to BLKn (where n is an integer of 1 or more), and each of these blocks BLK0 to BLKn includes a plurality of memory cells, a plurality of word lines, a plurality of bit lines, and the like. The peripheral circuit 112 performs various operations related to functioning of the memory cell array 111. Each connection pad 113 is a connection terminal for permitting the memory device 101 to communicate with the memory controller 102 via the bus 103.

The peripheral circuit 112 includes an input/output circuit 121, a logic control circuit 122, a command register 123, an address register 124, a sequencer 125, a driver 126, a row decoder 127, and a sense amplifier 128.

The input/output circuit 121 is electrically connected to the connection pad 113 for an input/output signal (I/O). While depicted as a singular I/O line/pad, the single I/O line/pad may represent a plurality of I/O lines/pads in an actual device. The input/output circuit 121 receives an input signal from the memory controller 102 and transmits an output signal to the memory controller 102. The input/output circuit 121 sorts the input signal from the memory controller 102 into a command CMD, an address ADD, and/or data DAT. These input signals are transferred to the command register 123, the address register 124, and the sense amplifier 128, respectively. The input/output circuit 121 also receives data DAT from the sense amplifier 128 (e.g., as the result of a reading operation) and outputs this data DAT to the memory controller 102 as an output signal.

The logic control circuit 122 receives signals CLE, ALE, WEn, and REn from the memory controller 102. The logic control circuit 122 transmits a signal RBn to the memory controller 102.

The signal CLE (command latch enable) is a signal notifying that the incoming input signal from the memory controller 102 is a command CMD. The signal ALE (address latch enable) is a signal notifying that the incoming input signal from the memory controller 102 is an address ADD. The signal WEn (write enable-negated) is a signal for the memory controller 102 to write data DAT into the memory device 101. The signal REn (read enable-negated) is a signal for the memory controller 102 to read data DAT from the memory device 101. The signal RBn (ready/busy-negated) is a signal indicating whether the memory device 101 is in a ready state or a busy state.

The command register 123 stores the command CMD transferred from the input/output circuit 121. The command CMD can be, for example, an instruction for causing the sequencer 125 to execute a write operation, a read operation, an erasing operation, or the like.

The address register 124 stores the address ADD transferred from the input/output circuit 121. The address ADD includes, for example, a page address PAd, a block address BAd, a column address CAd, and the like.

The sequencer 125 controls the overall operations of the memory device 101. The sequencer 125 controls, for example, the driver 126, the row decoder 127, and the sense amplifier 128 to execute a write operation, a read operation, and an erasing operation.

The driver 126 generates voltage(s) used in the write operation, the read operation, the erasing operation, and the like. The driver 126 further applies the generated voltage(s) to a signal line corresponding to a selected word line based on the page address PAd stored in the address register 124.

The row decoder 127 selects a block based on the block address BAd stored in the address register 124. With this configuration, the row decoder 127 can apply the voltage generated by the driver 126 from the signal line to the word line(s) of a particular block.

The sense amplifier 128 applies a predetermined voltage to the bit lines when writing the data DAT received from the memory controller 102 into the memory cell array 111. With this configuration, the data DAT can be written into predetermined memory cells. On the other hand, when the sense amplifier 128 reads out stored data from the memory cell array 111, the sense amplifier 128 determines the data values of the stored data in predetermined memory cells based on the voltage on the bit lines. With this configuration, the stored data can be read out from the memory cells as the data DAT, and this read data DAT can be transmitted to the memory controller 102. The operation of the sense amplifier 128 is controlled by the sequencer 125 based on the column address CAd stored in the address register 124.

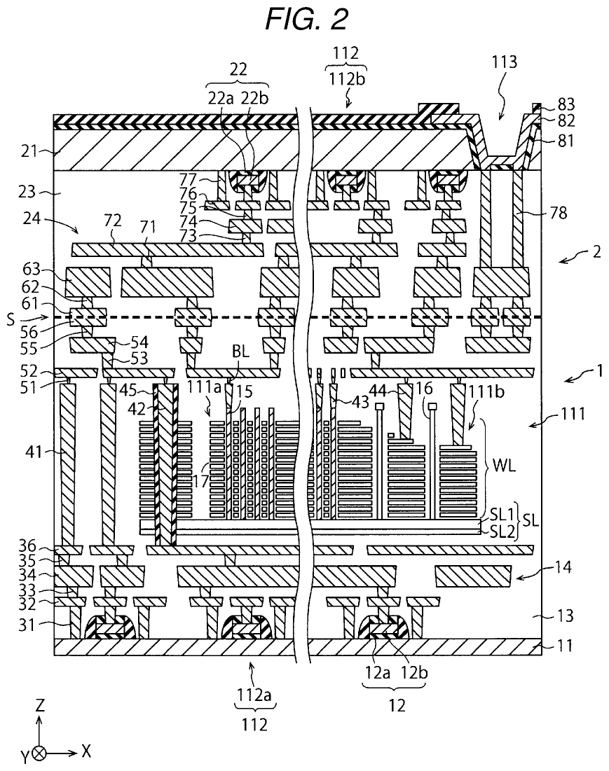

FIG. 2 is a cross-sectional view illustrating a structure of the semiconductor device of the first embodiment.

FIG. 2 illustrates a vertical cross section of the memory device 101 in the semiconductor device illustrated in FIG. 1. FIG. 2 illustrates the memory cell array 111, the peripheral circuit 112, the connection pad 113, and the like in the memory device 101. As illustrated in FIG. 2, the semiconductor device (memory device 101) of this embodiment includes a memory chip in which an array chip 1 and a circuit chip 2 are bonded together.

In this specification, the +Z-direction is generally referred to as an upward direction, and the −Z-direction is generally referred to as a downward direction. The −Z-direction may coincide with or may not coincide with the direction of gravity.

The array chip 1 includes a substrate 11, a plurality of transistors 12, an interlayer insulating film 13, and a multilayer wiring structure 14. The substrate 11 is an example of a first substrate, and these transistors 12 are examples of first and third transistors. The array chip 1 further includes a cell region 111a and a staircase region 111b in the memory cell array 111 and a lower peripheral circuit 112a in the peripheral circuit 112. Therefore, the array chip 1 of this embodiment includes the memory cell array 111 and a part of the peripheral circuit 112.

The circuit chip 2 includes a substrate 21, a plurality of transistors 22, an interlayer insulating film 23, and a multilayer wiring structure 24. The substrate 21 is an example of a second substrate, and these transistors 22 are examples of second and fourth transistors. The circuit chip 2 further includes an upper peripheral circuit 112b in the peripheral circuit 112 and a connection pad 113. Therefore, the circuit chip 2 of this embodiment includes the rest of the peripheral circuit 112.

The substrate 11 is a semiconductor substrate such as a silicon substrate. Each transistor 12 includes a gate insulating film 12a and a gate electrode 12b formed in this order on the upper surface of the substrate 11, and a source diffusion layer and a drain diffusion layer (not illustrated) formed in the substrate 11. Each transistor 12 is, for example, a high breakdown voltage transistor having a thick gate insulating film 12a.

The interlayer insulating film 13 is formed on the upper surface of the substrate 11 so as to cover each transistor 12. The interlayer insulating film 13 is a stacked insulating film including various insulating films such as a silicon oxide film. The multilayer wiring structure 14 is formed in the interlayer insulating film 13 and includes various wiring layers, plugs, metal pads, and the like. Further details of the multilayer wiring structure 14 will be described later

The memory cell array 111 is formed in the interlayer insulating film 13 above the substrate 11, and includes the cell region 111a and the staircase region 111b. The memory cell array 111 includes, as a plurality of electrode layers, a plurality of word lines WL and a source line SL continuously formed in the cell region 111a and the staircase region 111b. These electrode layers are separated from each other in the Z-direction above the substrate 11. The source line SL of this embodiment includes a semiconductor layer SL1 formed under these word lines WL and a metal layer SL2 formed under the semiconductor layer SL1. In FIG. 2, the staircase region 111b is positioned in the X-direction of the cell region 111a.

The cell region 111a includes a plurality of columnar portions 15. These columnar portions 15 extend in the Z-direction and penetrate the plurality of word lines WL in the cell region 111a. These columnar portions 15 form a plurality of memory cells together with these word lines WL. Each columnar portion 15 is electrically connected to the source line SL on the lower end side and electrically connected to a bit line BL on the upper end side. Each columnar portion 15 includes a channel semiconductor layer and a charge storage layer, as will be described later. The word line WL in the cell region 111a is an example of a first portion.

The staircase region 111b includes a plurality of beam portions 16. These beam portions 16 extend in the Z-direction and penetrate the plurality of word lines WL in the staircase region 111b. In the staircase region 111b of this embodiment, these word lines WL have an upward staircase structure. The word line WL in the staircase region 111b is an example of a second portion.

The memory cell array 111 further includes a plurality of insulating films 17 formed between the word lines WL adjacent to each other and between the lowest word line WL and the source line SL. These insulating films 17 electrically insulate the word line WL and the source line SL from each other. Each insulating film 17 is, for example, a silicon oxide film.

The lower peripheral circuit 112a is formed by the plurality of transistors 12 provided on the upper surface of the substrate 11. In this example, the lower peripheral circuit 112a includes the row decoder 127 illustrated in FIG. 1.

The substrate 21 is a semiconductor substrate such as a silicon substrate. Each transistor 22 includes a gate insulating film 22a and a gate electrode 22b formed in this order on the lower surface of the substrate 21, and a source diffusion layer and a drain diffusion layer (not illustrated) formed in the substrate 21. Each transistor 22 is, for example, a low breakdown voltage transistor having a thick gate insulating film 22a. In this embodiment, the film thickness of the gate insulating film 12a of each transistor 12 is set to be thicker than the film thickness of the gate insulating film 22a of each transistor 22. In this case, a depletion layer of each transistor 12 is generally longer than a depletion layer of each transistor 22. Although the thickness of the substrate 11 appears thinner than the thickness of the substrate 21 in FIG. 2, the thickness of the substrate 11 is preferably thicker than the substrate 21 in an actual device corresponding this embodiment.

The interlayer insulating film 23 is formed on the lower surface of the substrate 21 so as to cover each transistor 22. The interlayer insulating film 23 can be a silicon oxide film or a stacked insulating film including various insulating films. The interlayer insulating film 23 is bonded to the interlayer insulating film 13. FIG. 2 illustrates a bonding surface S (bonding interface) between the interlayer insulating film 13 and the interlayer insulating film 23. The upper surface of the interlayer insulating film 13 and the lower surface of the interlayer insulating film 23 are in contact with each other at the bonding surface S. The multilayer wiring structure 24 is formed in the interlayer insulating film 23, and includes various wiring layers, plugs, vias, metal pads, and the like.

The upper peripheral circuit 112b is formed by the plurality of transistors 22 provided on the lower surface of the substrate 21. The upper peripheral circuit 112b comprises, for example, the sense amplifier 128 illustrated in FIG. 1.

In this first embodiment, the connection pads 113 are formed on the interlayer insulating film 23 in the substrate 21. The connection pad 113 may be electrically connected to the upper peripheral circuit 112b via the multilayer wiring structure 24, for example, or may be electrically connected to the memory cell array 111 or the lower peripheral circuit 112a via the multilayer wiring structures 14 and 24.

The multilayer wiring structure 14 in the array chip 1 includes a plurality of contact plugs 31 provided on the substrate 11 and a wiring layer 32 provided on these contact plugs 31 and including a plurality of wirings. Each contact plug 31 is formed, for example, on the gate electrode 12b, source diffusion layer, or drain diffusion layer of the corresponding transistor 12, and is electrically connected to the corresponding transistor 12. The multilayer wiring structure 14 further includes via plugs 33 provided on the wiring layer 32 and a wiring layer 34 provided on the via plugs 33 and including a plurality of wirings. The multilayer wiring structure 14 further includes via plugs 35 provided on the wiring layer 34 and a wiring layer 36 provided on the via plugs 35 and including a plurality of wirings.

The multilayer wiring structure 14 further includes a plurality of via plugs 41 provided on the wiring layers 36 outside the memory cell array 111, and a vertical wiring layer 42 provided on the wiring layer 36 in the memory cell array 111. The multilayer wiring structure 14 further includes a plurality of contact plugs 43 respectively provided on the upper surfaces of the plurality of columnar portions 15 in the cell region 111a, and a plurality of contact plugs 44 respectively provided on the upper surfaces of the plurality of word lines WL in the staircase region 111b. The vertical wiring layer 42 is provided in the memory cell array 111 via an insulating film 45. Each contact plug 43 electrically connects the corresponding columnar portion 15 and the corresponding bit line BL. The plurality of contact plugs 44 are examples of a plurality of plugs.

The multilayer wiring structure 14 further includes these via plugs 41, the vertical wiring layer 42, the contact plugs 43, a wiring layer 51 provided on the contact plugs 44 and including a plurality of wirings, and a wiring layer 52 provided on the wiring layer 51 and including a plurality of wirings. The wiring in the wiring layer 51 includes the bit line BL. The multilayer wiring structure 14 further includes a plurality of via plugs 53 provided on the wiring layer 52, and a wiring layer 54 provided on the via plugs 53 and including the plurality of wirings. The multilayer wiring structure 14 further includes a plurality of via plugs 55 provided on the wiring layer 54, and a plurality of metal pads 56 respectively provided on the via plugs 55. Each metal pad 56 includes, for example, a Cu (copper) layer. These metal pads 56 are examples of first pads.

The multilayer wiring structure 24 in the circuit chip 2 includes a plurality of metal pads 61 respectively provided on these metal pads 56, a plurality of via plugs 62 respectively provided these metal pads 61, and a wiring layer 63 provided on these via plugs 62 and including a plurality of wirings. Each metal pad 61 includes, for example, a Cu layer. These metal pads 61 are examples of second pads. Each metal pad 61 is bonded to the corresponding metal pad 56 on the bonding surface S. The bonding surface S of this embodiment is positioned between the memory cell array 111 and the substrate 21.

The multilayer wiring structure 24 further includes a plurality of via plugs 71 provided on the wiring layer 63, and a wiring layer 72 provided on the via plugs 71 and including a plurality of wirings. The multilayer wiring structure 24 further includes a plurality of via plugs 73 provided on the wiring layer 72, and a wiring layer 74 provided on the via plugs 73 and including a plurality of wirings. The multilayer wiring structure 24 further includes a plurality of via plugs 75 provided on the wiring layer 74, and a wiring layer 76 provided on the via plugs 75 and including a plurality of wirings. The multilayer wiring structure 24 further includes a plurality of contact plugs 77 provided on the wiring layer 76 and under the substrate 21, and a plurality of via plugs 78 provided on the wiring layer 63. Each contact plug 77 is formed, for example, under the gate electrode 22b, source diffusion layer, or drain diffusion layer of the corresponding transistor 22, and is electrically connected to the corresponding transistor 22.

The circuit chip 2 further includes an insulating film 81, a metal layer 82, and a passivation insulating film 83 in this order formed on the upper surface of the substrate 21. The insulating film 81 and the metal layer 82 are further formed in this order on the side surface of the substrate 21 and the upper surface of the interlayer insulating film 23 in an opening provided in the substrate 21. The metal layer 82 is further formed on the plurality of via plugs 78 in the opening, and is electrically connected to these via plugs 78. The metal layer 82 includes, for example, an Al (aluminum) layer. A part of the metal layer 82 is exposed from the passivation insulating film 83 and functions as the connection pad 113. The circuit chip 2 of this embodiment may include a plurality of connection pads 113 having the same structure as the connection pad 113 illustrated in FIG. 2.

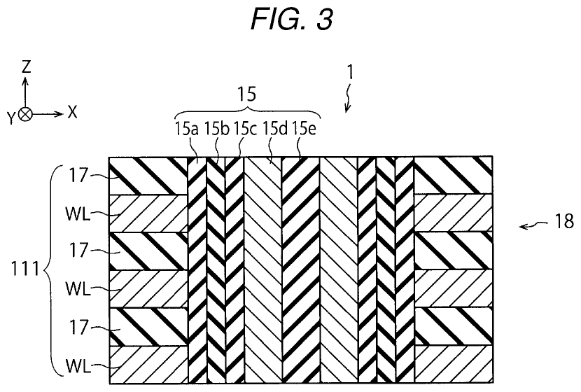

FIG. 3 is an enlarged cross-sectional view illustrating the structure of the semiconductor device of the first embodiment.

FIG. 3 illustrates the memory cell array 111 provided in the array chip 1 and a single columnar portion 15 provided in the memory cell array 111. The memory cell array 111 includes a stacked film 18 including a plurality of word line WLs and a plurality of insulating films 17 alternately. Each word line WL includes, for example, a W (tungsten) layer.

As illustrated in FIG. 3, each columnar portion 15 of this embodiment includes a block insulating film 15a, a charge storage layer 15b, a tunnel insulating film 15c, a channel semiconductor layer 15d, and a core insulating film 15e provided in this order in the stacked film 18 and extending in the Z-direction. The block insulating film 15a, the tunnel insulating film 15c, and the core insulating film 15e are, for example, a silicon oxide film or a metal insulating film. The charge storage layer 15b is an insulating film such as a silicon nitride film, and is formed on the side surfaces of the word line WL and insulating film 17 via the block insulating film 15a. The charge storage layer 15b may be a semiconductor layer such as a polysilicon layer. The channel semiconductor layer 15d is, for example, a polysilicon layer, and is formed on the side surface of the charge storage layer 15b via the tunnel insulating film 15c. The charge storage layer 15b is formed between the side surfaces of the word line WL and insulating film 17 and the side surface of the channel semiconductor layer 15d.

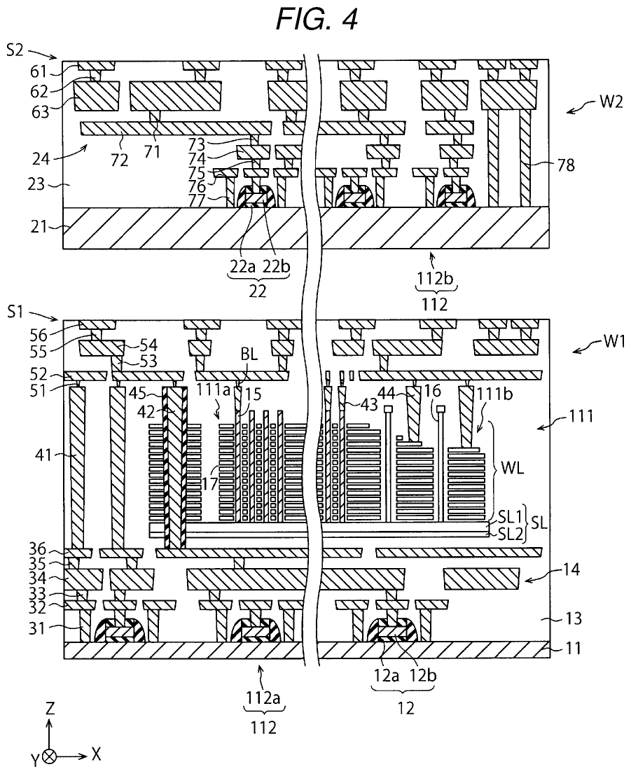

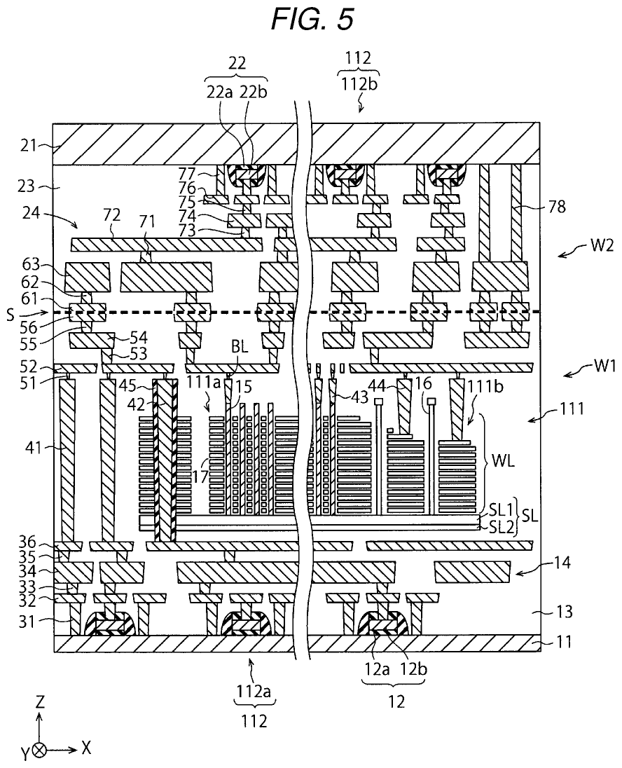

FIGS. 4 and 5 are cross-sectional views illustrating a method for manufacturing the semiconductor device of the first embodiment.

FIG. 4 illustrates an array wafer W1 including a plurality of array chips 1 and a circuit wafer W2 including a plurality of circuit chips 2. The orientation of the circuit wafer W2 in FIG. 4 is opposite to the orientation of the circuit chip 2 in FIG. 2. In this embodiment, the semiconductor device (memory device 101) is manufactured by bonding the array wafer W1 and the circuit wafer W2. FIG. 4 illustrates the circuit wafer W2 before the orientation is reversed for bonding, and FIG. 2 illustrates the circuit chip 2 after being bonded and diced with the orientation reversed for bonding. FIG. 4 illustrates an upper surface S1 of the array wafer W1 and an upper surface S2 of the circuit wafer W2.

First, as illustrated in FIG. 4, the transistor 12, the interlayer insulating film 13, the multilayer wiring structure 14, the memory cell array 111, the lower peripheral circuit 112a, and the like are formed on the substrate 11 of the array wafer W1, and the transistor 22, the interlayer insulating film 23, the multilayer wiring structure 24, the upper peripheral circuit 112b, and the like are formed on the substrate 21 of the circuit wafer W2.

For example, the lower peripheral circuit 112a including the transistor 12 is formed on the substrate 11, and the memory cell array 111 including the cell region 111a and the staircase region 111b is formed above the lower peripheral circuit 112a. The memory cell array 111 includes the plurality of word lines WL and the plurality of columnar portions 15 penetrating these word lines WL. Furthermore, the contact plugs 43 are formed on these columnar portions 15, the contact plugs 44 are formed on these word lines WL, and then the metal pads 56 are formed above the contact plugs 43 and 44. On the other hand, the upper peripheral circuit 112b including the transistor 22 is formed on the substrate 21, and the wiring layer 63, the via plugs 62, the metal pads 61, and the like are formed in this order above the upper peripheral circuit 112b.

Next, as illustrated in FIG. 5, the array wafer W1 and the circuit wafer W2 are bonded together by mechanical pressure. With this configuration, the interlayer insulating film 13 and the interlayer insulating film 23 are adhered to each other. Next, the array wafer W1 and the circuit wafer W2 are annealed at 400° C. With this configuration, the metal pad 56 and the metal pad 61 are joined.

After that, the array wafer W1 and the circuit wafer W2 are cut into a plurality of memory chips. In this way, the semiconductor device illustrated in FIG. 2 is manufactured. The insulating film 81, the metal layer 82, the passivation insulating film 83, and the connection pad 113 of FIG. 2 are formed on the substrate 21 after annealing the array wafer W1 and the circuit wafer W2, for example.

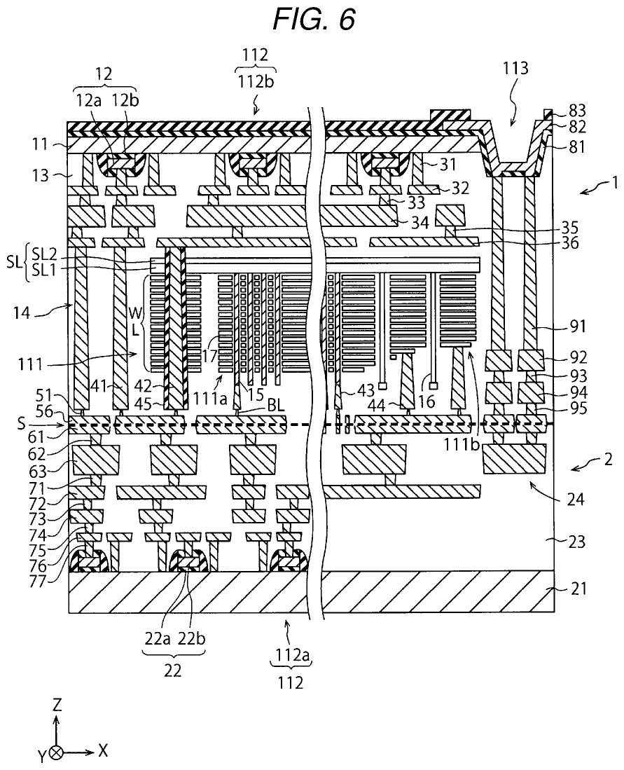

Although the array wafer W1 and the circuit wafer W2 are bonded together in this embodiment, the array wafers W1 may be bonded to each other instead. The aspects described above with reference to FIGS. 1 to 5 and those related to FIGS. 6 to 14 may also be applied to bonding of array wafers W1 to each other.

Although FIG. 2 illustrates a boundary surface between the interlayer insulating film 13 and the interlayer insulating film 23 and a boundary surface between the metal pad 56 and the metal pad 61, however, these boundary surfaces are generally not observable after the annealing step(s). However, the position of these boundary surfaces may be estimated, for example, by detecting an inclination of the side surface of the metal pad 56 or the side surface of the metal pad 61, or by noting a positional deviation between the metal pad 56 and the metal pad 61.

FIG. 2 illustrates a semiconductor device in a chip state, and FIG. 5 illustrates a semiconductor device in a wafer state. A semiconductor device of this embodiment may be sold as product after being cut into a plurality of chips (e.g., FIG. 2) or may sold as a product before being cut into a plurality of chips (e.g., FIG. 5). In this embodiment, a plurality of chip-shaped semiconductor devices (FIG. 1) are manufactured from one wafer-shaped semiconductor device (FIG. 5).

FIG. 6 is a cross-sectional view illustrating a structure of the semiconductor device of a first modification of the first embodiment.

The first embodiment semiconductor device of FIG. 2 includes the circuit chip 2 on the array chip 1, whereas the semiconductor device in this first modification (FIG. 6) includes the array chip 1 on the circuit chip 2.

Similar to the array chip 1 of the first embodiment, the array chip 1 of this modification includes a substrate 11, a plurality of transistors 12, an interlayer insulating film 13, a multilayer wiring structure 14, and a memory cell array 111. However, the orientation of these components in this modification is opposite to the orientation of these components in the first embodiment. For example, in the memory cell array 111 of this modification, the word line WL in the staircase region 111b has a downward staircase structure, and the contact plugs 44 are provided on the lower surface of the word lines WL. In this modification, the substrate 11 is an example of the second substrate, and the transistors 12 are examples of the second and fourth transistors.

Similar to the first embodiment, the circuit chip 2 of this modification includes a substrate 21, a plurality of transistors 22, an interlayer insulating film 23, and a multilayer wiring structure 24. However, the orientation of these components in this modification is opposite to the orientation of these components in the first embodiment. For example, the metal pad 61 of this modification is provided under the metal pad 56. In this modification, the substrate 21 is an example of the first substrate, and the transistors 22 are examples of the first and third transistors.

The semiconductor device of this modification is different from the semiconductor device of the first embodiment in the following points.

First, the lower peripheral circuit 112a of this modification is formed by the plurality of transistors 22, which are provided on the upper surface of the substrate 21, and the upper peripheral circuit 112b of this modification is formed by the plurality of transistors 12, which are provided on the lower surface of the substrate 11. The lower peripheral circuit 112a of this modification includes the row decoder 127 illustrated in FIG. 1. The upper peripheral circuit 112b of this modification includes the sense amplifier 128 illustrated in FIG. 1.

Each transistor 22 of this modification is a high breakdown voltage transistor having a thick gate insulating film 22a. On the other hand, each transistor 12 in this modification is a low breakdown voltage transistor having a thin gate insulating film 12a. In this modification, the film thickness of the gate insulating film 22a of each transistor 22 is set to be thicker than the film thickness of the gate insulating film 12a of each transistor 12. In this case, the depletion layer of each transistor 22 is generally longer than the depletion layer of each transistor 12. For that reason, the thickness of the substrate 21 of this modification is preferably set to be thicker than the thickness of the substrate 11.

The array chip 1 of this modification does not include the wiring layer 52, the via plugs 53, the wiring layer 54, and the via plugs 55. Instead, the array chip 1 of this modification includes a plurality of via plugs 95 provided on the plurality of metal pads 56, and a wiring layer 94 (provided on the via plugs 95) including a plurality of wirings. The array chip 1 of this modification further includes a plurality of via plugs 93 provided on the wiring layer 94, a wiring layer 92 (provided on the) via plugs 93 including a plurality of wirings, and a plurality of via plugs 91 provided on the wiring layer 92. The metal pad 56 of this modification is provided under the via plug 95 and the wiring layer 51.

The insulating film 81, the metal layer 82, and the passivation insulating film 83 of this modification are not provided on the circuit chip 2 side but on the array chip 1 side. In this modification, the insulating film 81, the metal layer 82, and the passivation insulating film 83 are formed in this order on the upper surface of the substrate 11. The insulating film 81 and the metal layer 82 are further formed in this order on the side surface of the substrate 11 and the upper surface of the interlayer insulating film 13 in the opening provided in the substrate 11. The metal layer 82 is formed on the plurality of via plugs 91 in the opening and electrically connected to these via plugs 91. A part of the metal layer 82 is exposed from the passivation insulating film 83 and functions as a connection pad 113. The array chip 1 of this modification may include a plurality of connection pads 113 having the same structure as the connection pad 113 illustrated in FIG. 6.

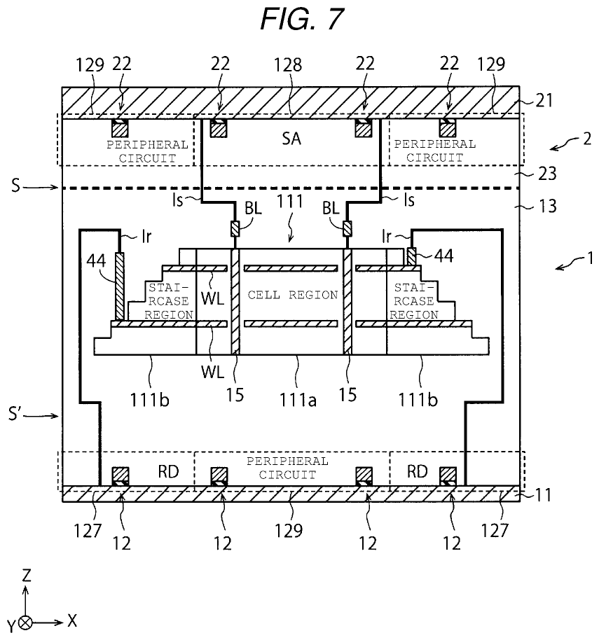

FIG. 7 is a cross-sectional view illustrating additional aspects of the structure of the semiconductor device of the first embodiment. FIG. 7 schematically illustrates the structure of the semiconductor device depicted in FIG. 2.

The semiconductor device depicted in FIG. 7 includes the circuit chip 2 on the array chip 1. The array chip 1 includes the substrate 11, the transistors 12, the interlayer insulating film 13, the memory cell array 111, and the like. The circuit chip 2 includes the substrate 21, the transistors 22, the interlayer insulating film 23, and the like. The memory cell array 111 in FIG. 7 includes one cell region 111a and two staircase regions 111b provided on the ±X-direction sides of the cell region 111a. FIG. 7 further illustrates two of the word line WLs in the memory cell array 111, two of the columnar portions 15 in the cell region 111a, and two of the contact plugs 44 on the staircase region 111b.

The peripheral circuit 112 of this embodiment includes the lower peripheral circuit 112a formed by the transistors 12, which are on the upper surface of the substrate 11, and the upper peripheral circuit 112b formed by the transistors 22, which are on the lower surface of the substrate 21 (see FIG. 2). That is, the peripheral circuit 112 is divided between the upper surface of the substrate 11 and the lower surface of the substrate 21. That is, the peripheral circuit 112 comprises the lower peripheral circuit 112a and the upper peripheral circuit 112b.

As illustrated in FIG. 7, the peripheral circuit 112 includes the row decoder (RD) 127 in the lower peripheral circuit 112a, the sense amplifier (SA) 128 in the upper peripheral circuit 112b, and other circuits 129 in the lower peripheral circuit 112a and the upper peripheral circuit 112b. The other circuits 129 may be, for example, the input/output circuit 121, the logic control circuit 122, the command register 123, the address register 124, the sequencer 125, and/or the driver 126. Hereinafter, the other circuits 129 are also referred to as a “peripheral circuit 129”.

The row decoder 127 of this embodiment is divided into two portions on the upper surface of the substrate 11. These portions can be referred to as “two divided portions of the row decoder 127”. Similarly, peripheral circuit 129 of this embodiment has portions (three portions) provided on the upper surface of the substrate 11 and the lower surface of the substrate 21. These portions are referred to as “three divided portions of the peripheral circuit 129”.

Each divided portion of the row decoder 127 includes one or more transistors 12. FIG. 7 illustrates one transistor 12 provided in each divided portion of the row decoder 127. In this example, each transistor 12 in the row decoder 127 is a high breakdown voltage transistor having a thick gate insulating film 12a. Each transistor 12 in the row decoder 127 is an example of a first transistor.

FIG. 7 illustrates two wirings Ir that electrically connect a transistor 12 in the row decoder 127 to a contact plug 44 on the staircase region 111b. Each wiring Ir comprises, for example, a contact plug 31, a wiring layer 32 portion, a via plug 33, a wiring layer 34 portion, a via plug 35, a wiring layer 36 portion, a via plug 41, a vertical wiring layer 42 portion, and the like (see FIG. 2). Each transistor 12 in the row decoder 127 of this embodiment is electrically connected to a corresponding contact plug 44 by a wiring Ir. As illustrated in FIG. 7, each wiring Ir may include a portion extending in the Z-direction and a portion extending in an XY plane.

Each divided portion of the row decoder 127 of this embodiment is positioned in the −Z-direction below a staircase region 111b. That is each of the two divided portions of the row decoder 127 is directly under one of the staircase regions 111b. In FIG. 7, the two transistors 12 in the row decoder 127 portions are positioned directly under the staircase regions 111b.

The sense amplifier 128 includes one or more transistors 22. FIG. 7 illustrates two transistors 22 provided in the sense amplifier 128. In this example, each transistor 22 in the sense amplifier 128 is a low breakdown voltage transistor having a thin gate insulating film 22a. Each transistor 22 in the sense amplifier 128 is an example of a second transistor.

FIG. 7 illustrates two wirings Is that electrically connect a transistor 22 in the sense amplifier 128 to one of the columnar portions 15 in the cell region 111a. Each wiring Is comprises, for example, a contact plug 43, a wiring layer 51 portion, a wiring layer 52 portion, a via plug 53, a wiring layer 54 portion, a via plug 55, a metal pad 56, a metal pad 61, a via plug 62, a wiring layer 63 portion, a via plug 71, a wiring layer 72 portion, a via plug 73, a wiring layer 74 portion, a via plug 75, a wiring layer 76 portion, a contact plug 77, and the like (see FIG. 2). Each transistor 22 in the sense amplifier 128 of this embodiment is electrically connected to the channel semiconductor layer 15d in a corresponding columnar portion 15 by a wiring Is (see FIG. 3). As illustrated in FIG. 7, each wiring Is of this embodiment may include a portion extending in the Z-direction and a portion extending in an XY plane.

The sense amplifier 128 of this embodiment is positioned in the +Z-direction of the cell region 111a, that is, directly above the cell region 111a. In FIG. 7, two transistors 22 in the sense amplifier 128 are positioned directly above the cell region 111a.

Each divided portion of the peripheral circuit 129 includes one or more transistors 12 or one or more transistors 22. FIG. 7 illustrates two transistors 12 provided in one divided portion of the peripheral circuit 129 and one transistor 22 provided each of the other divided portions of the peripheral circuit 129. In this example, each transistor 12 in the peripheral circuit 129 is a high breakdown voltage transistor having a thick gate insulating film 12a, and each transistor 22 in the peripheral circuit 129 is a low breakdown voltage transistor having a thin gate insulating film 22a. Each transistor 12 in the peripheral circuit 129 is an example of a third transistor. Each transistor 22 in the peripheral circuit 129 is an example of a fourth transistor. For example, the input/output circuit 121, the logic control circuit 122, the command register 123, the address register 124, and the sequencer 125 illustrated in FIG. 1 are preferably formed by the transistors 22 (e.g., low breakdown voltage transistors), and the driver 126 illustrated in FIG. 1 is preferably formed by the transistors 12 (e.g., high breakdown voltage transistors).

The peripheral circuit 129 of this embodiment includes a divided portion that is positioned directly under the cell region 111a, a divided portion that is positioned directly above a staircase region 111b, and another divided portion positioned directly above another staircase region 111b. In FIG. 7, the transistors 12 in the peripheral circuit 129 are positioned directly under the cell region 111a, and the transistors 22 in the peripheral circuit 129 are positioned directly above staircase regions 111b.

The semiconductor device of this embodiment has a structure in which the array chip 1 and the circuit chip 2 are bonded to each other at the bonding surface S. The bonding surface S is provided between the memory cell array 111 and the upper peripheral circuit 112b. In other examples, the semiconductor device may have a structure in which three or more chips are bonded together. For example, the semiconductor device of this embodiment may have a structure in which a chip including the memory cell array 111 and a chip including the upper peripheral circuit 112b are bonded together at the bonding surface S, and then a chip including the lower peripheral circuit 112a is bonded to the chip including the memory cell array 11 at a bonding surface S′. As illustrated in FIG. 7, the bonding surface S′ is provided between the memory cell array 111 and the lower peripheral circuit 112a.

In this embodiment, the peripheral circuit 112 is disposed not only in circuit chip 2 but also in array chip 1. Specifically, the peripheral circuit 112 of this embodiment includes the lower peripheral circuit 112a provided on the upper surface of the substrate 11 in the array chip 1 and the upper peripheral circuit 112b provided on the lower surface of the substrate 21 in the circuit chip 2.

If the peripheral circuit 112 is disposed only on the lower surface of the substrate 21, the required peripheral circuit 112 planar size may limit the reduction of the chip area of the semiconductor device (memory device 101, memory chip) of FIG. 2. One reason for this is that the arrangement of the memory cells in the memory cell array 111 has a three-dimensional structure, whereas the arrangement of the transistors in the peripheral circuit 112 has a generally two-dimensional structure. For example, a planar area of the memory cell array 111 may be reduced relatively easily by increasing the Z-direction dimension of the memory cell array 111 (e.g., by stacking more word lines WL), but it is usually more difficult to reduce the planar area occupied by the peripheral circuit 112 in a similar manner.

However, the peripheral circuit 112 of this embodiment is disposed not only on the lower surface of the substrate 21 but also on the upper surface of the substrate 11. With this configuration, the arrangement of the transistors in the peripheral circuit 112 is not limited to a two-dimensional structure on a single plane (lower surface of substrate 21), but rather also has a two-dimensional structure on a second plane (upper surface of substrate 11 in addition to lower surface of substrate 21). Therefore, according to this embodiment, it is possible to reduce the chip area of the semiconductor device of FIG. 2 by reducing the overall (non-overlapped) planar area occupied by the peripheral circuit 112.

When the peripheral circuit 112 is disposed on both the lower surface of the substrate 21 and the upper surface of the substrate 11, deciding which particular circuit types to be disposed on different substrate surfaces and associated circuit designs may be a problem. For example, if an appropriate policy is not adopted, a layout of the wirings that electrically connects the memory cell array 111 and the peripheral circuit 112 may become complicated, and/or performance of the transistors in the peripheral circuit 112 may deteriorate.

In this example, the row decoder 127 is disposed on the upper surface of the substrate 11, and the sense amplifier 128 is disposed on the lower surface of the substrate 21. In this embodiment, the transistor 12 is a high breakdown voltage transistor, and the transistor 22 is a low breakdown voltage transistor. In such a case, the transistor 12 in the row decoder 127 and the transistor 22 in the sense amplifier 128 are preferably disposed on different substrates. Thus, in this example, the row decoder 127 is disposed on the upper surface of the substrate 11, and the sense amplifier 128 is disposed on the lower surface of the substrate 21. Thus, the transistors 12 and the transistors 22 can be formed on different substrates.

Since the transistor 12 in the row decoder 127 is electrically connected to the contact plug 44 on the staircase region 111b, the row decoder 127 is preferably disposed near the staircase region 111b. On the other hand, since the transistor 22 in the sense amplifier 128 is electrically connected to the columnar portion 15 in the cell region 111a, the sense amplifier 128 is preferably disposed near the cell region 111a. For that reason, the row decoder 127 of this embodiment is disposed directly under the staircase region 111b on the upper surface of the substrate 11, and the sense amplifier 128 is disposed directly above the cell region 111a on the lower surface of the substrate 21. With this configuration, the peripheral circuit 129 can be disposed directly under the cell region 111a on the upper surface of the substrate 11 or disposed directly above the staircase region 111b on the lower surface of the substrate 21.

When determining the layout of peripheral circuit 129, the high breakdown voltage transistor in the peripheral circuit 129 is preferably disposed on the upper surface of the substrate 11 together with the transistor 12 (e.g., high breakdown voltage transistor) in the row decoder 127, and the low breakdown voltage transistor in the peripheral circuit 129 is preferably disposed on the lower surface of the substrate 21 together with the transistor 22 (e.g., low breakdown voltage transistor) in the sense amplifier 128. For that reason, the input/output circuit 121, the logic control circuit 122, the command register 123, the address register 124, and the sequencer 125 in the peripheral circuit 129 are preferably disposed on the lower surface of the substrate 21, and the driver 126 in the peripheral circuit 129 is preferably disposed on the upper surface of the substrate 11 (see FIG. 1). With this configuration, it is possible to adopt a structure in which the thickness of the substrate 11 is increased for the high breakdown voltage transistors and the thickness of the substrate 21 is reduced for the low breakdown voltage transistors.

If both the row decoder 127 and the sense amplifier 128 are disposed on the upper surface of the substrate 11, the space where the peripheral circuit 129 is disposed on the upper surface of the substrate 11 may be insufficient for both. Similarly, if both the row decoder 127 and the sense amplifier 128 are disposed on the lower surface of the substrate 21, the space where the peripheral circuit 129 is disposed on the lower surface of the substrate 21 may be insufficient both. Therefore, the row decoder 127 and the sense amplifier 128 are preferably disposed on different substrates.

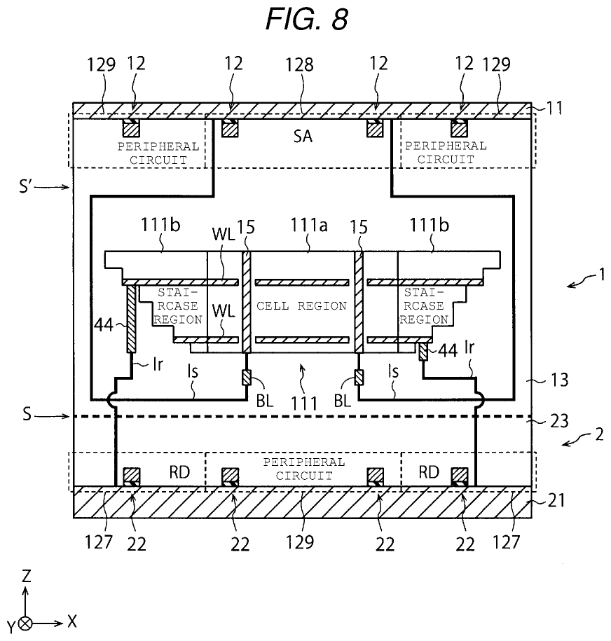

FIG. 8 is a cross-sectional view illustrating a structure of a semiconductor device of a first modification of the first embodiment. FIG. 8 schematically illustrates the structure of the semiconductor device of FIG. 6.

The semiconductor device (FIG. 8) of this modification includes the array chip 1 on the circuit chip 2 as described above. The array chip 1 includes the substrate 11, the transistors 12, the interlayer insulating film 13, the memory cell array 111, and the like. The circuit chip 2 includes the substrate 21, the transistors 22, the interlayer insulating film 23, and the like. Similar to the memory cell array 111 of FIG. 7, the memory cell array 111 of FIG. 8 includes one cell region 111a and two staircase regions 111b provided in the ±X-direction of the cell region 111a. Similar to FIG. 7, FIG. 8 illustrates two of the word lines WL in the memory cell array 111, two of the columnar portions 15 in the cell region 111a, and two of the contact plugs 44 under the staircase region 111b.

The peripheral circuit 112 of this modification includes the lower peripheral circuit 112a formed by the transistors 22 on the upper surface of the substrate 21 and the upper peripheral circuit 112b formed by the transistors 12 on the lower surface of the substrate 11 (see FIG. 6). That is, the peripheral circuit 112 of this modification is provided on both the upper surface of the substrate 21 and the lower surface of the substrate 11 by being divided into the lower peripheral circuit 112a and the upper peripheral circuit 112b.

As illustrated in FIG. 8, the peripheral circuit 112 of this modification includes the row decoder 127 provided in the lower peripheral circuit 112a, the sense amplifier 128 provided in the upper peripheral circuit 112b, and the peripheral circuit 129 with portions provided in the lower peripheral circuit 112a and the upper peripheral circuit 112b. FIG. 8 illustrates two divided portions of the row decoder 127 provided on the upper surface of the substrate 21 and three divided portions of the peripheral circuit 129.

Each divided portion of the row decoder 127 includes one or more transistors 22. FIG. 8 illustrates one transistor 22 provided in each divided portion of the row decoder 127. Each transistor 22 is, for example, a high breakdown voltage transistor having a thick gate insulating film 22a. Each transistor 22 in the row decoder 127 is an example of a first transistor.

FIG. 8 illustrates two wirings Ir that electrically connect a transistor 22 in the row decoder 127 to a contact plug 44 under the staircase region 111b. Each wiring Ir is formed by, for example, a wiring layer 51 portion, a metal pad 56, a metal pad 61, a via plug 62, a wiring layer 63 portion, a via plug 71, a wiring layer 72 portion, a via plug 73, a wiring layer 74 portion, a via plug 75, a wiring layer 76 portion, a contact plug 77, and the like (see FIG. 6). Each transistor 22 in the row decoder 127 of this modification is electrically connected to a corresponding contact plug 44 by a wiring Ir. As illustrated in FIG. 8, each wiring Ir may include a portion extending in the Z-direction and a portion extending in an XY plane.

One divided portion of the row decoder 127 in this modification is positioned in the −Z-direction of one staircase region 111b, that is, directly under the staircase region 111b. Similarly, the other divided portion of the row decoder 127 in this modification is positioned in the −Z-direction of the other staircase region 111b, that is, directly under the staircase region 111b. In FIG. 8, two transistors 22 in the row decoder 127 are positioned directly under these staircase regions 111b.

The sense amplifier 128 includes one or more transistors 12. FIG. 8 illustrates two transistors 12 provided in the sense amplifier 128. Each transistor 12 in the sense amplifier 128 is, for example, a low breakdown voltage transistor having a thin gate insulating film 12a. Each transistor 12 in the sense amplifier 128 is an example of the second transistor.

FIG. 8 illustrates two wirings Is that electrically connect the transistors 12 in the sense amplifier 128 and the columnar portions 15 in the cell region 111a. Each wiring Is formed by, for example, the contact plug 31, the wiring layer 32, the via plug 33, the wiring layer 34, the via plug 35, the wiring layer 36, the via plug 41, the vertical wiring layer 42, the wiring layer 51, and the like (see FIG. 6). Each transistor 12 in the sense amplifier 128 in this modification is electrically connected to the channel semiconductor layer 15d in the corresponding columnar portion 15 by a wiring Is (see FIG. 3). As illustrated in FIG. 8, each wiring Is in this modification may include a portion extending in the Z-direction and a portion extending an XY plane.

The sense amplifier 128 in this modification is positioned in the +Z-direction of the cell region 111a, that is, directly above the cell region 111a. In FIG. 8, two transistors 12 in the sense amplifier 128 are positioned directly above the cell region 111a.

Each divided portion of the peripheral circuit 129 includes one or more transistors 22 or one or more transistors 12. FIG. 8 illustrates two transistors 22 provided in one divided portion of the peripheral circuit 129, one transistor 12 provided in another divided portion of the peripheral circuit 129, and one transistor 12 provided in another divided portion of the peripheral circuit 129. Each transistor 22 in the peripheral circuit 129 is, for example, a high breakdown voltage transistor having a thick gate insulating film 22a, and each transistor 12 in the peripheral circuit 129 is, for example, a low breakdown voltage transistor having a thin gate insulating film 12a. Each transistor 22 in the peripheral circuit 129 is an example of the third transistor. Each transistor 12 in the peripheral circuit 129 is an example of the fourth transistor. For example, the input/output circuit 121, the logic control circuit 122, the command register 123, the address register 124, and the sequencer 125 illustrated in FIG. 1 are preferably formed by the transistors 12 (e.g., low breakdown voltage transistors), and the driver 126 illustrated in FIG. 1 is preferably formed by the transistors 22 (e.g., high breakdown voltage transistors).

The peripheral circuit 129 in this modification includes a divided portion positioned directly under the cell region 111a, a divided portion positioned directly above one staircase region 111b, and a divided portion positioned directly above the other staircase region 111b. In FIG. 8, two transistors 22 in the peripheral circuit 129 are positioned directly under the cell region 111a, and two transistors 12 in the peripheral circuit 129 are positioned directly above these staircase regions 111b.

The semiconductor device of this modification has a structure in which the array chip 1 and the circuit chip 2 are bonded to each other on the bonding surface S. The bonding surface S is between the memory cell array 111 and the lower peripheral circuit 112a. In other examples, the semiconductor device may have a structure in which three or more chips are bonded together. For example, the chip including the memory cell array 111 and the chip including the lower peripheral circuit 112a can be bonded together on the bonding surface S. The chip including the memory cell array 111 can be bonded to a chip including the upper peripheral circuit 112b at the bonding surface S′. The bonding surface S′ is between the memory cell array 111 and the upper peripheral circuit 112b, for example, as illustrated in FIG. 8.

Similar to the peripheral circuit 112 of the first embodiment, the peripheral circuit 112 in this modification is disposed not only in the circuit chip 2 but also in the array chip 1. Specifically, the peripheral circuit 112 of this modification includes the upper peripheral circuit 112b provided on the lower surface of the substrate 11 in the array chip 1 and the lower peripheral circuit 112a provided on the upper surface of the substrate 21 in the circuit chip 2. According to this modification, it is possible to reduce the necessary chip area of the semiconductor device of FIG. 6 by reducing the overall planar area required by the peripheral circuit 112.

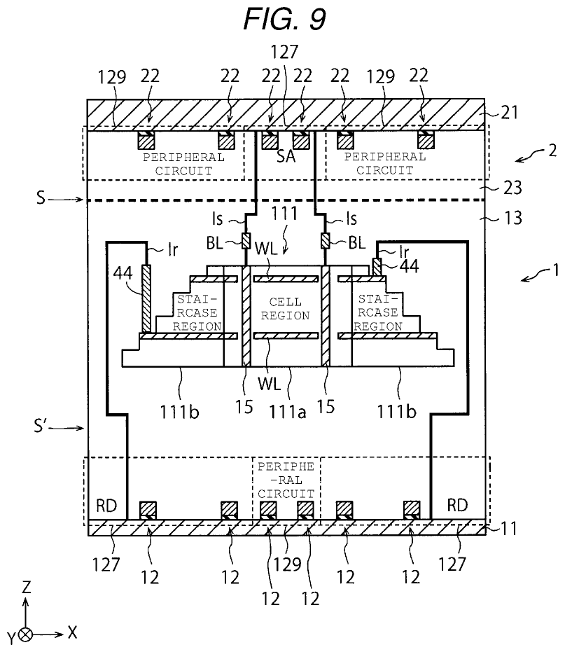

FIG. 9 is a cross-sectional view illustrating a structure of a semiconductor device of a second modification of the first embodiment. The semiconductor device (FIG. 9) of this second modification has the same structure as the semiconductor device of FIG. 7. However, divided portions of the row decoder 127 of this second modification include a portion positioned directly under the corresponding staircase region 111b and a portion positioned directly under the cell region 111a. The divided portions of the row decoder 127 in this second modification include a transistor 12 positioned directly under the corresponding staircase region 111b and a transistor 12 positioned directly under the cell region 111a. The transistor 12 positioned directly under the staircase region 111b and the transistor 12 positioned directly under the cell region 111a are each electrically connected to a corresponding contact plug 44 by a wiring Ir. These transistors 12 are examples of a first transistor.

Divided portions of the peripheral circuit 129 under the substrate 21 in this second modification include a portion positioned directly above the corresponding staircase region 111b and a portion positioned directly above the cell region 111a. The divided portions of the peripheral circuit 129 under the substrate 21 in this modification include a transistor 22 positioned directly above the corresponding staircase region 111b and a transistor 22 positioned directly above the cell region 111a. These transistors 22 are examples of a fourth transistor.

Aspects of the semiconductor device of FIG. 7 and the semiconductor device of FIG. 9 are compared.

In general, the area of the cell region 111a is often relatively large, but the area of each staircase region 111b is often comparatively small. Thus, in the semiconductor device illustrated in FIG. 7, the area of each divided portion of the row decoder 127 and the area of each divided portion of the peripheral circuit 129 under the substrate 21 may be relatively small, and the space where the transistors 12 and 22 for these divided portions are to be disposed may not be insufficient.

Therefore, as depicted in the semiconductor device of FIG. 9, each divided portion of the row decoder 127 may also include a portion that is disposed directly under the cell region 111a. Similarly, each divided portion of the peripheral circuit 129 under the substrate 21 can also include a portion disposed directly above the cell region 111a. With this configuration, it is possible to allocate a sufficient space where the transistors 12 and 22 for these divided portions can be disposed. As a result, the chip area of the semiconductor device can be further reduced.

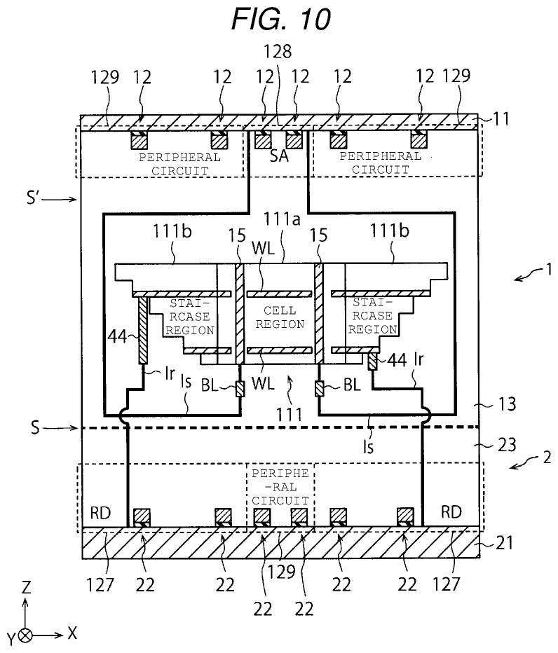

FIG. 10 is a cross-sectional view illustrating a structure of a semiconductor device of a third modification of the first embodiment. The semiconductor device (FIG. 10) of this third modification has the same general structure as the semiconductor device of FIG. 8.

However, divided portions of the row decoder 127 of this third modification include a portion positioned directly under the corresponding staircase region 111b and a portion positioned directly under the cell region 111a. Thus, divided portions of the row decoder 127 of this third modification include a transistor 22 positioned directly under the corresponding staircase region 111b and a transistor 22 positioned directly under the cell region 111a. The transistor 22 positioned directly under the staircase region 111b and the transistor 22 positioned directly under the cell region 111a are each electrically connected to a corresponding contact plug 44 by a wiring Ir. These transistors 22 are examples of a first transistor.

Divided portions of the peripheral circuit 129 under the substrate 11 in this third modification include a portion positioned directly above the corresponding staircase region 111b and a portion positioned directly above the cell region 111a. Thus, the divided portions of the peripheral circuit 129 under the substrate 11 in this modification include a transistor 12 positioned directly above the corresponding staircase region 111b and a transistor 12 positioned directly above the cell region 111a. These transistors 12 are examples of a fourth transistor.

Aspects of the semiconductor device of FIG. 8 and the semiconductor device of FIG. 10 are compared.

In general, the area of the cell region 111a is often relatively large, but the area of each staircase region 111b is often comparatively small. For that reason, in the semiconductor device illustrated in FIG. 8, the area for each divided portion of the row decoder 127 and the area for each divided portion of the peripheral circuit 129 under the substrate 11 may be small, and the space where the transistors 22 and 12 for these divided portions are to be disposed may be insufficient.

Therefore, in the semiconductor device of FIG. 10, each divided portion of the row decoder 127 can also include a portion disposed directly under the cell region 111a, and similarly each divided portion of the peripheral circuit 129 under the substrate 11 can also include a portion disposed directly above the cell region 111a. With this configuration, it is possible to allocate a sufficient space where the transistors 22 and 12 for these divided portions can be disposed. As a result, the chip area of the semiconductor device can be further reduced.

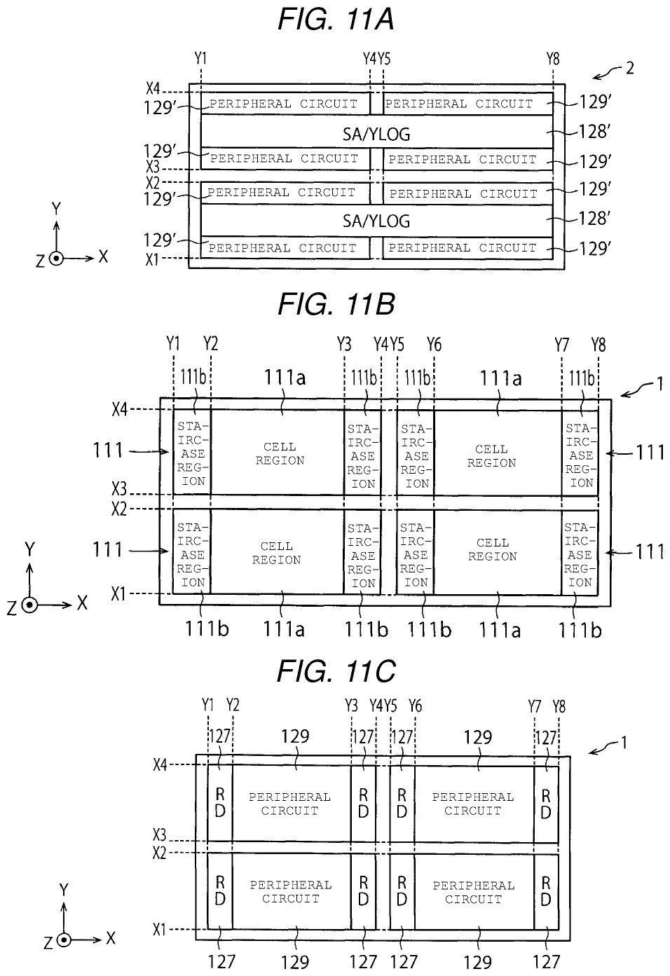

FIGS. 11A, 11B, and 11C are plan views illustrating aspects of the structure of the semiconductor device of the first embodiment.

Positions of lines X1, X2, X3, X4, Y1, Y4, Y5, and Y8 in FIG. 11A, lines X1, X2, X3, X4 and Y1-Y8 in FIG. 11B, and lines X1, X2, X3, X4 and Y1-Y8 in FIG. 11C indicate positions that are respectively overlapping with each other in the Z-direction. For example, the line X1 illustrated in FIG. 11A is directly above the line X1 in FIG. 11B and the line X1 in FIG. 11C.

FIG. 11A illustrates a planar structure of the upper peripheral circuit 112b in the circuit chip 2 illustrated in FIGS. 2 and 7. The upper peripheral circuit 112b includes two SA/YLOG 128′ including the sense amplifier (SA) 128 and YLOG, and eight peripheral circuits 129′ including other circuits in the upper peripheral circuit 112b. These SA/YLOG 128′ and peripheral circuits 129′ have a planar shape longer in the X-direction.

FIG. 11B illustrates a planar structure of the array chip 1 illustrated in FIGS. 2 and 7. The array chip of this embodiment may include four memory cell arrays 111, as illustrated in FIG. 11B. However, FIGS. 2 and 7 illustrate just one of these memory cell arrays 111. Each memory cell array 111 includes a cell region 111a and two staircase regions 111b provided on the ±X-direction sides of the cell region 111a.

FIG. 11C illustrates the planar structure of the lower peripheral circuit 112a in the array chip 1 illustrated in FIGS. 2 and 7. The lower peripheral circuit 112a includes eight row decoders 127 (“RDs 127”) and four peripheral circuits 129. Each peripheral circuit 129 is disposed between two row decoders 127. Each peripheral circuit 129 illustrated in FIG. 11C corresponds to one divided portion of the peripheral circuit 129 on the substrate 11 illustrated in FIG. 7, and the two row decoders 127 illustrated in FIG. 11C correspond to two divided portions of the row decoder 127 illustrated in FIG. 7.

Each memory cell array 111 illustrated in FIG. 11B is positioned directly under one SA/YLOG 128′ and two peripheral circuits 129′ illustrated in FIG. 11A, and is positioned directly above two row decoders 127 (portion) and one peripheral circuit 129 (portion) illustrated in FIG. 11C.

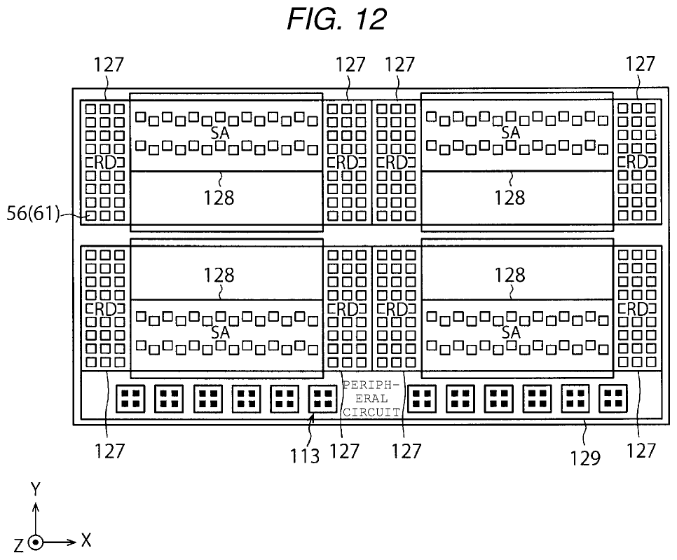

FIG. 12 is another plan view illustrating the structure of the semiconductor device of the first embodiment.

FIG. 12 illustrates the planar structure of the peripheral circuit 112 illustrated in FIGS. 2 and 7. The peripheral circuit 112 illustrated in FIG. 12 includes eight RDs 127 similar to those in FIG. 11C, four SAs 128, and the peripheral circuit 129. FIGS. 2 and 7 illustrate two of these RDs 127 and one of these SAs 128. Each SA 128 is disposed between two RDs 127 in plan view.

The semiconductor device of this first embodiment includes a plurality of metal pads 56 illustrated by white (open) squares in FIG. 12 and a plurality of connection pads 113 illustrated by black (filled) squares in FIG. 12. The metal pads 61 of this embodiment can be disposed at the same positions as the metal pads 56 in plan view.

In this embodiment, the RDs 127 and the SAs 128 are disposed not overlap to each other in plan view. Thus, the metal pads 56 and 61 for the RDs 127 are disposed directly above the RDs 127 to be electrically connected to the RDs 127, and the metal pads 56 and 61 for the SAs 128 are disposed directly under the SAs 128 to be electrically connected to the SAs 128. The connection pads 113 illustrated in FIG. 12 are grouped in groups of four connection pads 113 and are disposed on the peripheral circuit 129.

The structures illustrated in FIGS. 11 and 12 may also be applied to the semiconductor device of each of the described modifications.

As described above, the peripheral circuit 112 of this first embodiment is disposed not only in the circuit chip 2 but also in the array chip 1. The row decoder 127 of this first embodiment includes transistors 12 provided directly under the staircase region 112b on the substrate 11, and the sense amplifier 128 includes transistors 22 provided directly above the cell region 112a under the substrate 21. Therefore, the chip area of the semiconductor device can be reduced.

### Second Embodiment

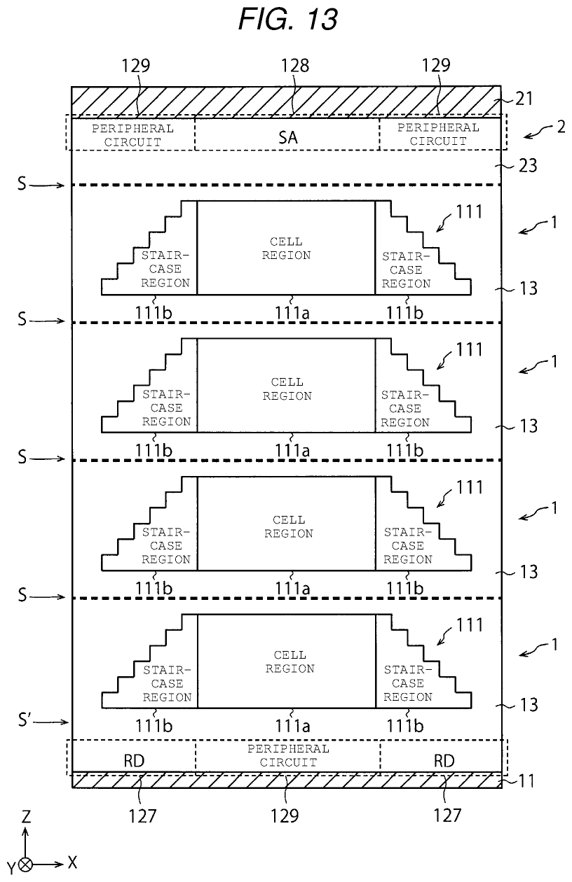

FIG. 13 is a cross-sectional view illustrating a structure of a semiconductor device of a second embodiment. FIG. 13 schematically illustrates a vertical cross section of the memory device 101 in the semiconductor device illustrated in FIG. 1.

As illustrated in FIG. 13, the semiconductor device of this second embodiment includes a memory chip in which a plurality of array chips 1 are bonded together with a circuit chip 2. The circuit chip 2 illustrated in FIG. 13 may have substantially the same structure as that of the circuit chip 2 illustrated in FIG. 7. The lowest array chip 1 (farthest away from circuit chip 2 in the Z direction) illustrated in FIG. 13 may have substantially the same structure as that of the array chip 1 illustrated in FIG. 7. Each of the other array chips 1 illustrated in FIG. 13 has a structure corresponding to that in which the substrate 11 and the lower peripheral circuit 112a have been removed from the array chip 1 illustrated in FIG. 7. However, in FIG. 13, the transistors 12 and 22, the word line WL, the columnar portion 15, the contact plug 44, the wirings Ir and Is, and the like are not particularly illustrated in order to make the drawing easier to understand.

In FIG. 13, four array chips 1 are stacked on one another. FIG. 13 thus illustrates three bonding surfaces S between these stacked array chips 1. Each array chip 1 includes one memory cell array 111. Therefore, four memory cell arrays 111 are provided between the substrate 11 and the substrate 21 while being separated from each other in the Z-direction. These memory cell arrays 111 are examples of the first and second memory cell arrays, and the word lines WL in these memory cell arrays 111 are examples of the first and second electrode layers.

In FIG. 13, the circuit chip 2 is stacked on the uppermost array chip 1. FIG. 13 thus illustrates one bonding surface S between the array chip 1 and the circuit chip 2. Similar to the circuit chip 2 of the first embodiment, the circuit chip 2 of this second embodiment includes the sense amplifier 128 and two divided portions of the peripheral circuit 129. In this second embodiment, the sense amplifier 128 is disposed directly above the cell region 111a of each memory cell array 111, and these divided portions of the peripheral circuit 129 are disposed directly above two staircase regions 111b of each memory cell array 111.

Similar to the array chip 1 of the first embodiment, the lowermost array chip 1 of this second embodiment includes two divided portions of the row decoder 127 and one divided portion of the peripheral circuit 129. These divided portions of the row decoder 127 are disposed below the two staircase regions 111b of each memory cell array 111, and the divided portion of the peripheral circuit 129 is disposed below the cell regions 111a of each memory cell array 111.

The row decoder 127, the sense amplifier 128, and the peripheral circuit 129 of this second embodiment may have also have the layout similar to that illustrated in FIG. 9.

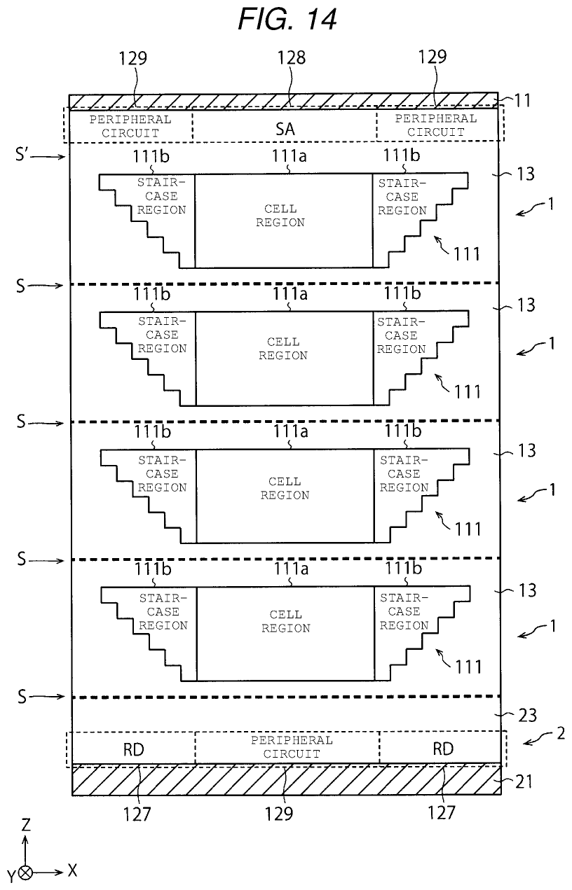

FIG. 14 is a cross-sectional view illustrating a structure of a semiconductor device of a modification of the second embodiment. FIG. 14 schematically illustrates a modified vertical cross section of the memory device 101 in the semiconductor device illustrated in FIG. 1.

As illustrated in FIG. 14, the semiconductor device of this modification includes a memory chip in which a plurality of array chips 1 and one circuit chip 2 are bonded together. The circuit chip 2 illustrated in FIG. 14 has the substantially same structure as that of the circuit chip 2 illustrated in FIG. 8. The uppermost array chip 1 illustrated in FIG. 14 has substantially the same structure as that of the array chip 1 illustrated in FIG. 8. The other array chips 1 illustrated in FIG. 14 have a structure corresponding to the removal of the substrate 11 and the upper peripheral circuit 112b from the array chip 1 that was illustrated in FIG. 8. However, in FIG. 14, the transistors 12 and 22, the word line WL, the columnar portion 15, the contact plug 44, the wirings Ir and Is, and the like are not specifically illustrated in order to make the drawing easier to understand.

In FIG. 14, four array chips 1 are stacked on one another. FIG. 14 illustrates three bonding surfaces S between these array chips 1. Each array chip 1 includes one memory cell array 111. Therefore, four memory cell arrays 111 are provided between the substrate 11 and the substrate 21 while being separated from each other in the Z-direction. These memory cell arrays 111 are examples of the first and second memory cell arrays, and the word lines WL in these memory cell arrays 111 are examples of the first and second electrode layers.

In FIG. 14, the lowest array chip 1 is stacked on the circuit chip 2. FIG. 14 illustrates one bonding surface S between the array chip 1 and the circuit chip 2. Similar to the circuit chip 2 of the first modification of the first embodiment, the circuit chip 2 of this modification includes two divided portions of the row decoder 127 and one divided portion of the peripheral circuit 129. In this modification, these divided portions of the row decoder 127 are disposed below two staircase regions 111b of the memory cell arrays 111, and a peripheral circuit 129 portion is disposed below the cell regions 111a of the memory cell arrays 111.

Similarly to the array chip 1 of the first modification of the first embodiment, the uppermost array chip 1 of this modification of the second embodiment includes the sense amplifier 128 and two divided portions of the peripheral circuit 129. In this modification, the sense amplifier 128 is disposed above the cell regions 111a, and divided portions of the peripheral circuit 129 are disposed above the two staircase regions 111b.

The row decoder 127, the sense amplifier 128, and the peripheral circuit 129 of this modification of the second embodiment may have the layout illustrated in FIG. 10.

According to second embodiment, similar to the first embodiment, the chip area of the semiconductor device can be reduced. According to this second embodiment, by manufacturing one semiconductor device using a plurality of array chips 1, it is possible to improve the degree of integration of the semiconductor device and further reduce the chip area of the semiconductor device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first substrate;
a plurality of electrode layers above the first substrate in a first direction, the electrode layers separated from each other in the first direction;
a plurality of plugs on upper surfaces or lower surfaces of the plurality of electrode layers;
a plurality of columnar portions extending in the first direction through the plurality of electrode layers, each columnar portion including a semiconductor layer and a charge storage layer that is between the semiconductor layer and the plurality of electrode layers;
a second substrate above the plurality of electrode layers in the first direction;
a plurality of first transistors on an upper surface of the first substrate and electrically connected to the plurality of plugs; and
a plurality of second transistors on a lower surface of the second substrate and electrically connected to the plurality of columnar portions.

2. The semiconductor device according to claim 1, wherein a film thickness of a gate insulating film of the first transistor is thicker than a film thickness of a gate insulating film of the second transistor.

3. The semiconductor device according to claim 1, further comprising:
a memory cell array including the plurality of electrode layers;
a row decoder including the first transistor on the upper surface of the first substrate; and
a sense amplifier including the second transistor on the lower surface of the second substrate.

4. The semiconductor device according to claim 3, further comprising:
a plurality of third transistors on the upper surface of the first substrate, wherein
the third transistors are portions of a peripheral circuit other than the row decoder.

5. The semiconductor device according to claim 4, wherein
a film thickness of a gate insulating film of the first transistor is thicker than a film thickness of a gate insulating film of the second transistor, and
film thickness of a gate insulating film of the third transistor is thicker than the film thickness of the gate insulating film of the second transistor.

6. The semiconductor device according to claim 4, further comprising:
a plurality of fourth transistors on the lower surface of the second substrate, wherein
the fourth transistors are provided in the peripheral circuit other than the sense amplifier.

7. The semiconductor device according to claim 6, wherein
a film thickness of a gate insulating film of the first transistor is thicker than a film thickness of a gate insulating film of the second transistor, and
the film thickness of the gate insulating film of the first transistor is thicker than a film thickness of a gate insulating film of the fourth transistor.

8. The semiconductor device according to claim 1, further comprising:
a plurality of first pads between the plurality of electrode layers and the second substrate; and
a plurality of second pads on the plurality of first pads, wherein
the second transistors are electrically connected to the columnar portions via a first pad and a second pad.

9. The semiconductor device according to claim 1, further comprising:
a plurality of first pads between the first substrate and the plurality of electrode layers; and
a plurality of second pads on the plurality of first pads, wherein
the first transistors are electrically connected to the plugs via a first pad and a second pad.

10. The semiconductor device according to claim 1, further comprising:
a first memory cell array including a first electrode layer among the plurality of electrode layers;
a second memory cell array above the first memory cell array and including a second electrode layer among the plurality of electrode layers;
a row decoder including the first transistor on the upper surface of the first substrate; and
a sense amplifier including the second transistor on the lower surface of the second substrate.

11. The semiconductor device according to claim 1, wherein
the plurality of electrode layers comprises a first portion and a second portion adjacent to the first portion in a second direction intersecting the first direction,
the plurality of columnar portions are in the first portion of the plurality of electrode layers, and
the plurality of plugs are on an upper surface or a lower surface of the second portion of the plurality of electrode layers.

12. The semiconductor device according to claim 11, wherein the plurality of first transistors includes at least one transistor positioned directly under the second portion in the first direction.

13. The semiconductor device according to claim 12, wherein the plurality of first transistors further includes a transistor positioned directly under the first portion in the first direction.

14. The semiconductor device according to claim 12, further comprising:
a plurality of third transistors on the upper surface of the first substrate, wherein
the plurality of third transistors includes at least one transistor positioned directly under the first portion in the first direction.

15. The semiconductor device according to claim 11, wherein the plurality of second transistors includes a transistor positioned directly above the first portion in the first direction.

16. The semiconductor device according to claim 15, further comprising:
a plurality of fourth transistors on the lower surface of the second substrate, wherein
the plurality of fourth transistors includes a transistor positioned directly above the second portion in the first direction.

17. The semiconductor device according to claim 16, wherein the plurality of fourth transistors further includes at least one transistor positioned directly above the first portion in the first direction.

18. The semiconductor device according to claim 11, further comprising:
a memory cell array comprising the first and second portions of the plurality of electrode layers;
a row decoder on the upper surface of the first substrate and comprising the first transistor, the row decoder having a portion directly under the second portion in the first direction; and
a sense amplifier on the lower surface of the second substrate and comprising the second transistor, the sense amplifier including a portion directly above the first portion in the first direction.

19. The semiconductor device according to claim 18, further comprising:
a plurality of first pads between the first substrate and the plurality of electrode layers; and
a plurality of second pads on the plurality of first pads, wherein
the plurality of first pads include:
first pads directly above the row decoder and electrically connected to the row decoder, and
first pads directly under the sense amplifier and electrically connected to the sense amplifier; and
the plurality of second pads include:
second pads directly above the row decoder and electrically connected to the row decoder, and
second pads directly under the sense amplifier and electrically connected to the sense amplifier.

20. A method for manufacturing a semiconductor device comprising:
forming a plurality of first transistors on a first substrate;
forming a plurality of second transistors on a second substrate;
forming a plurality of electrode layers that are separated from each other in the first direction, the plurality of electrode layers being either above the first transistors on the first substrate or above the second transistors on the second substrate;
forming a plurality of plugs on the plurality of electrode layers;
forming a plurality of columnar portions extending in the first direction through the plurality of electrode layers, each columnar portion including a semiconductor layer and a charge storage layer between the semiconductor layer and the plurality of electrode layers; and
bonding the first substrate and the second substrate together, wherein
the plurality of first transistors are electrically connected to the plurality of plugs, and
the plurality of second transistors are electrically connected to the plurality of columnar portions.
